(19) United States
(12) Patent Application Publication
(10) Pub. No.: US 2024/0258033 A1
(43) Pub. Date: Aug. 1, 2024

(54) Ceramic Phase Capacitors Devices for RF System in Photoactive Glass Substrates

(71) Applicant: 3D Glass Solutions, Inc., Albuquerque, NM (US)

(72) Inventors: Jeb H. Flemming, Albuquerque, NM (US); Kyle McWethy, Albuquerque, NM (US)

(21) Appl. No.: 18/560,492

(22) PCT Filed: Jun. 2, 2022
(86) PCT No.: PCT/US2022/031993

§ 371 Date: Nov. 13, 2023

Related U.S. Application Data
(60) Provisional application No. 63/197,066, filed on Jun. 4, 2021.

(51) Int. Cl. H01G 4/12; H01G 4/012; H01G 4/40

(52) U.S. Cl. CPC H01G 4/129; H01G 4/012; H01G 4/40

(57) ABSTRACT

The present invention includes a ceramic phase capacitor device and a method of making the same, wherein the ceramic phase capacitor is formed in or on a photosensitive glass substrate comprising: a first capacitor electrode formed in or one the photosensitive glass substrate; a glass-crystalline dielectric formed in situ from the photosensitive glass substrate adjacent to the first capacitor electrode; and a second capacitor electrode formed in or one the photosensitive glass substrate adjacent to the glass-crystalline dielectric and opposite the first electrode.

### CROSS-REFERENCE TO RELATED APPLICATIONS

This is a PCT International Application which claims priority to U.S. Provisional Application Ser. No. 63/197,066 filed on Jun. 4, 2021, the entire contents of which are incorporated herein.

### STATEMENT OF FEDERALLY FUNDED RESEARCH

None.

### TECHNICAL FIELD OF THE INVENTION

The present invention relates in general to the field of RF lumped element devices for RF systems in a package photoactive glass substrates.

### BACKGROUND OF THE INVENTION

Without limiting the scope of the invention, its background is described in connection with RF lumped element devices.

Photosensitive glass structures have been suggested for a number of micromachining and microfabrication processes such as integrated electronic elements in conjunction with other elements, systems, or subsystems. Silicon microfabrication of traditional glass is expensive and low yield while injection modeling or embossing processes produce inconsistent shapes. Silicon microfabrication processes rely on expensive capital equipment; photolithography and reactive ion etching or ion beam milling tools that generally cost in excess of one million dollars each and require an ultra-clean, high-production silicon fabrication facility costing millions to billions more. Injection molding and embossing are less costly methods of producing a three-dimensional shapes but generate defects within the transfer or have differences due to the stochastic curing process. Ideal inductors would have zero resistance and zero capacitance. However, real inductors have “parasitic” resistance, inductors and capacitance.

Historically, inductor capacitance is called “inter-winding capacitance” based on the assumption that it is the result of charge separation between insulated coil windings. However, if the inductor is measured over a conducting ground plane, capacitance between the coil and the ground plane is also part of the measurement. The distance of the coil from the measurement ground plane and the effective dielectric constant of the measurement substrate affects the capacitance to ground. This partially explains how the test fixture affects the SRF measurement. The following equation shows how the SRF is related to inductance and capacitance in an LC circuit:

$$SRF = \frac{1}{2 π \sqrt{( LC )}} in Hz$$

where: L is the inductance in Henries, and C is the capacitance in Farads.

In addition to the additional inductance, capacitance and resistance eliminate losses from: (1) PCB interconnects; (2) Long metal redistribution line lengths; (3) Bond pads; (4) Solder balls; (5) Substrate losses and dielectric constant/loss tangent; and/or (6) inconsistent assembly.

From this equation, it is clear that in general, RF and/or microwave filters are made up of one or more coupled resonators and several different technologies can be used to make resonators/filters. The majority of the resonators/filters fall into one of three general categories: Lumped-Element, Microstrip Transmission Lines, and Coaxial Waveguide.

Lumped RF elements are a combination of inductors and ceramic phase capacitors (LC) filters are the simplest resonator structure used in RF and microwave filters and other devices. Lumped-element circuit consisting of parallel or series inductors and ceramic phases. An advantage of a lumped-element filters/devices is that they can be very compact but the disadvantages are that they have a low quality factor, large level of distortion/noise and relatively poor performance. As such lumped-element devices are not consider a viable option in RF/Microwave applications.

In the book Lumped Elements for RF and Microwave Circuits by Inder Bahl published in 2003 it is stated that, “[a]n ideal lumped element is not realizable even at lower microwave frequencies because of the associated parasitic reactances due to fringing fields”. At RF and microwave frequencies, each component has associated electric and magnetic fields and finite dissipative loss. Thus, such components store or release electric and magnetic energies across them and their resistance accounts for the dissipated power. The relative values of the C, L, and R components in these elements depend on the intended use of the LE. To describe their electrical behavior, equivalent circuit models for such components are commonly used. Lumped element equivalent circuit (EC) models consist of basic circuit elements (L, C, or R) with the associated parasitics denoted by subscripts. Accurate computer-aided design of MICs and MMICs requires a complete and accurate characterization of these components. This requires comprehensive models including the effect of ground plane, fringing fields, proximity effects, substrate material and thickness, conductor thickness, and associated mounting techniques and applications. Thus, an EC representation of a lumped element with its parasitics and their frequency-dependent characteristics is essential for accurate element modeling. An EC model consists of the circuit elements necessary to fully describe its response, including resonances, if any. Models can be developed using analytical, electromagnetic simulation, and measurement-based methods. The early models of lumped elements were developed using analytical semiempirical equations. In 1943, Terman published an expression for the inductance of a thin metallic straight line that was later improved by Caulton et al., who added the effect of metallization thickness. Wheeler presented an approximate formula for the inductance of a circular spiral inductor with reasonably good accuracy at lower microwave frequencies. This formula has been extensively used in the design of microwave lumped circuits. Others have discussed inductance calculations for several geometries. The theoretical modeling of microstrip inductors for MICs has usually been based on two methods: the lumped-element approach and the coupled-line approach. The lumped-element approach uses formulas for free-space inductance with ground plane effects. These frequency-independent formulas are useful only when the total length of the inductor is a small fraction of the operating wavelength and when interturn capacitance can be ignored. In the coupled-line approach, an inductor is analyzed using multiconductor coupled microstrip lines. This 10 Lumped Elements for RF and Microwave Circuits technique predicts the spiral inductor's performance reasonably well for two turns and up to about 18 GHz.

An earlier theory for the interdigital capacitor was published by Alley, and Joshi et al. presented modified formulas for these capacitors. Mondal reported a distributed model of the MIM capacitor based on the coupled-line approach. Pengelly et al. presented the first extensive results on different lumped elements on GaAs, including inductors and interdigital capacitors, with special emphasis on the Q-factor.

Pettenpaul et al. reported lumped-element models using numerical solutions along with basic microstrip theory and network analysis. In general, analytical models are good for estimating the electrical performance of lumped elements. The realization of lumped L, C, R elements at microwave frequencies is possible by keeping the component size much smaller than the operating wavelength.

However, when the component size becomes greater than 1/10, these components have undesirable associated parasitics such as resistance, capacitance, and inductance. At RF and higher frequencies, the reactances of the parasitics become more significant, with increasing frequency resulting in higher loss and spurious resonances. Thus, empirical expressions are not accurate enough to predict LE performance accurately. Once lumped elements are accurately characterized either by electromagnetic (EM) simulation or measurements, the parasitic reactances become an integral part of the component and their effects can be included in the design.

Recent advances in workstation computing power and user-friendly software make it possible to develop EM field simulators. These simulators play a significant role in the simulation of single and multilayer passive circuit elements such as transmission lines and their discontinuities; patches; multilayer components, namely, inductors, capacitors, resistors, via holes, airbridges, inductor transformers, packages, and so on; and passive coupling between various circuit elements. Accurate evaluation of the effects of radiation, surface waves and interaction between components on the performance of densely packed Monolithic Microwave Integrated Circuits (MMICs) can only be calculated using three-dimensional (3-D) EM simulators. The most commonly used method of developing accurate models for lumped elements is by measuring dc resistance and S-parameter data. This modeling approach gives quick and accurate results, although the results are generally limited to just the devices measured. EC model parameters are extracted by computer optimization, which correlates the measured dc and S-parameter data (one- or two-port data) up to 26 or 40 GHz depending on the application. The accuracy of the model parameter values can be as good as the measurement accuracy by using recently developed on-wafer calibration standards and techniques. The equivalent circuit models are valid mostly up to the first parallel resonant frequency (fᵣₑₛ). However, when a design is involved with harmonics, for example, a power amplifier with second and third harmonic terminations at the output, one requires either EM simulated data working up to the highest design frequency or a more complex model taking into account higher order resonances. If the operating frequency is lower than fᵣₑₛ/3, then the models discussed above are adequate. At RF and microwave frequencies, the resistance of LEs is quite different from their dc values due to the skin effect. When an RF signal is applied across a LE, due to the finite conductivity of the conductor material, EM fields penetrate a conductor only a limited depth along its cross section. The distance in the conductor over which the fields decrease to 1/e (about 36.9%) of the values at the surface is called depth of penetration, or skin depth. This effect is a function of frequency with the penetration depth decreasing with increasing frequency. The flow of RF current is limited to the surface only, resulting in higher RF surface resistance than the dc value. This effect is taken into account during accurate modeling of the resistive loss in the component.

Microstrip transmission lines, also known as a stripline, can make good resonators/filters and offer a better compromise in terms of size and performance than lumped element filters. The processes used to manufacture microstrip circuits is very similar to the processes used to manufacture printed circuit boards using a precision thin-film process but require using quartz, ceramic, sapphire substrates and lower resistance metals such as gold to obtain the performance required for low power/loss RF applications.

Coaxial Waveguide (CW) filters provide higher Q factor than planar transmission lines, and are used in high performance RF applications. The coaxial resonators may make use of high-dielectric constant materials to reduce their size. The size of CW filter scale inversely to the frequency the size can reach to less than 2 cm² at frequencies above 30 GHz on a ceramic substrate. The combination of a ceramic substrate and the physical size prevents the filter makes these filters expensive and large relative to other RF filters from and as such are not generally used in commercial portable, compact RF products.

One of the most common RF filters are surface acoustic wave (SAW) and/or bulk acoustic wave (BAW). Both SAW and BAW exhibit decreased signal to noise ratios as the frequency of operation exceeds the speed of sound in the piezoelectric material. Single crystal BAW devices have been shown to have higher performance but also suffer from a dramatic collapse of the signal to noise when the frequencies exceed the speed of sound of the piezoelectric material. The speed of sound of the piezoelectric material used in SAW and BAW filters limits their application to frequencies less than 3 GHz. BAW and SAW devices by themselves, lack the frequency selectivity needed for 5G performance often enabling multiple channels/frequencies/signals to overlap. This increases the noise floor to the desired communication signal substantially increasing the error rate and lost data.

Despite all of these advances, a need remains for improvements to existing devices that have increased signal to noise ratio, that are easy and inexpensive to build, and that eliminate losses from: (1) PCB interconnects; (2) Long metal redistribution line lengths; (3) Bond pads; (4) Solder balls; (5) Substrate losses and dielectric constant/loss tangent; and/or (6) inconsistent assembly.

### SUMMARY OF THE INVENTION

Normally a RF lump element device (Capacitor or Inductor) is made by creating a ceramic phase in the photodefinable glass and chemically etching the exposed material to create the physical Capacitor or Inductor structure. The reason for this was the nature of the selectivity of ceramic phase to the chemical etchant. The ceramic phase of the photodefinable glass etches tens of time faster than the glass phase of the photodefinable glass. However, research has shown the that the loss tangent of the ceramic phase is substantially lower than that of the glass phase of the of the photodefinable glass and that RF filters made using ceramic phase elements have much higher Qs than their glass phase counterparts.

In one embodiment, the present invention includes a method for creating a ceramic phase capacitor in or on photo-definable glass comprising the steps of: forming two or more capacitor electrodes of the ceramic phase capacitor on or in a photosensitive glass substrate, wherein a portion of the photosensitive glass substrate separates the two or more capacitor electrodes; exposing the portion of the photosensitive glass substrate that separates the two or more capacitor electrodes to an activating energy source; heating the photosensitive glass substrate above a glass transition temperature thereof for at least ten minutes; cooling the photosensitive glass substrate to transform the exposed portion of the photosensitive glass substrate to a glass-crystalline dielectric; and forming electrical connections to the two or more capacitor electrodes. In one aspect, the method further comprises forming the two or more capacitor electrodes in vias within the photosensitive glass substrate. In another aspect, the method further comprises forming the two or more capacitor electrodes on opposite surfaces of the photosensitive glass substrate. In another aspect, the method further comprises forming the glass-crystalline dielectric on a surface parallel to the photosensitive glass substrate, wherein the glass-crystalline dielectric is in a ceramic phase. In another aspect, the method further comprises connecting the ceramic phase capacitor to an isolator with integrated lump element devices in a system-in-a-package (SiP). In another aspect, the method further comprises connecting the ceramic phase capacitor to a circulator with integrated lump element devices in a SiP. In another aspect, the method further comprises connecting the ceramic phase capacitor to an RF filter with integrated lump element devices in a SiP. In another aspect, the method further comprises connecting the ceramic phase capacitor to at least one of a low-pass filter, a high-pass filter, a notch filter, a band-pass filter, or a transformer with integrated lump element devices in a SiP. In another aspect, the method further comprises connecting the ceramic phase capacitor to a power combiner or a power splitter in or on the photosensitive glass substrate. In another aspect, the method further comprises connecting the ceramic phase capacitor to one or more antennas, impedance matching elements, 50-ohm termination elements, integrated ground planes, RF shielding elements, electromagnetic interference shielding elements, RF Combiners, RF Splitters, transformers, switches, or diplexers.

In another embodiment, the present invention includes a ceramic phase capacitor device formed in or on a photosensitive glass substrate comprising: a first capacitor electrode formed in or on the photosensitive glass substrate; a glass-crystalline dielectric formed in situ from the photosensitive glass substrate adjacent to the first capacitor electrode; and a second capacitor electrode formed in or on the photosensitive glass substrate adjacent to the glass-crystalline dielectric and opposite the first electrode. In one aspect, the first and second capacitor electrodes are formed in vias within the photosensitive glass substrate. In another aspect, the first and second capacitor electrodes are formed on opposite surfaces of the photosensitive glass substrate. In another aspect, the glass-crystalline dielectric is formed on a surface parallel to the photosensitive glass substrate. In another aspect, the device further comprises a first metal connector connected to the first capacitor electrode and a second metal connector connected to the second capacitor electrode. In another aspect, the ceramic phase capacitor is connected to an isolator with integrated lump element devices and is in a SiP. In another aspect, the ceramic phase capacitor is connected to a circulator with integrated lump element devices and is in a SiP. In another aspect, the ceramic phase capacitor is connected to an RF filter with integrated lump element devices and is in a SiP. In another aspect, the ceramic phase capacitor is connected to at least one of a low-pass filter, a high-pass filter, a notch filter, a band-pass filter, or a transformer with integrated lump element devices and is in a SiP. In another aspect, the ceramic phase capacitor is connected to a power combineror a power splitter in or on the photsensitive glass substrate. In another aspect, the ceramic phase capacitor is connected to one or more antennas, impedance matching elements, 50-ohm termination elements, integrated ground planes, RF shielding elements, electromagnetic interference shielding elements, RF combiners, RF splitters, transformers, switches, power splitters, power combiners, or diplexers.

In another embodiment, the present invention includes a method for creating a ceramic phase capacitor in or on photo-definable glass comprising the steps of: forming two or more capacitor electrodes of the ceramic phase capacitor on or in a photosensitive glass substrate, wherein a portion of the photosensitive glass substrate separates the two or more capacitor electrodes; exposing the portion of the photosensitive glass substrate that separates the two or more capacitor electrodes to an activating energy source; heating the photosensitive glass substrate above a glass transition temperature thereof for at least ten minutes; cooling the photosensitive glass substrate to transform the exposed portion of the photosensitive glass substrate to a glass-crystalline dielectric; and forming electrical connections to the two or more capacitor electrodes. In one aspect, the method further comprises forming the two or more capacitor electrodes in vias within the photosensitive glass substrate. In another aspect, the method further comprises forming the two or more capacitor electrodes on opposite surfaces of the photosensitive glass substrate. In another aspect, the method further comprises forming the glass-crystalline dielectric on a surface parallel to the photosensitive glass substrate wherein the glass-crystalline dielectric is in a ceramic phase. In another aspect, the method further comprises connecting the ceramic phase capacitor to an isolator with integrated lump element devices is in a SiP. In another aspect, the method further comprises connecting the ceramic phase capacitor to a circulator with integrated lump element devices in a SiP. In another aspect, the method further comprises connecting the ceramic phase capacitor to an RF filter with integrated lump element devices in a SiP. In another aspect, the method further comprises connecting the capacitor to at least one of a low-pass filter, a high-pass filter, a notch filter, a band-pass filter, or a transformer, with integrated lump element devices in a SiP. In another aspect, the method further comprises connecting the capacitor to a power combiner or a power splitter in or on the photosensitive glass substrate. In another aspect, the method further comprises connecting the capacitor to one or more antennas, impedance matching elements, 50-ohm termination elements, integrated ground planes, RF shielding elements, electromagnetic interference shielding elements, RF Combiners, RF splitters, transformers, switches, power splitters, power combiners, or diplexers.

### BRIEF DESCRIPTION OF THE DRAWINGS

For a more complete understanding of the features and advantages of the present invention, reference is now made to the detailed description of the invention along with the accompanying figures and in which:

FIG. 1 shows a top view of ceramic phase capacitor in the volume of the photodefinable glass.

FIG. 2 shows a side view of a ceramic phase capacitor in the volume of the photodefinable glass.

FIG. 3 shows a top view of an in-plane ceramic phase capacitor in a photodefinable glass.

FIG. 4 shows a cross section/side view of an in-plane ceramic phase capacitor in a photodefinable glass.

FIG. 5 shows the Loss Tangent of a ceramic phase capacitor in photodefinable glass.

FIG. 6 shows the dielectric constant of a ceramic phase capacitor of photodefinable glass.

FIG. 7 shows the Loss Tangent of a ceramic phase capacitor vs a glass phase capacitor made in a photodefinable glass.

FIG. 8 shows the Dielectric Constant of a ceramic phase capacitor vs a glass phase capacitor made in a photodefinable glass.

FIG. 9 shows a LC tank circuit layout in photodefinable glass.

FIGS. 10A and 10B show schematics for an inductor made in photodefinable glass.

FIG. 11 shows a simulation of an 5 GHz LC Tank circuit for a ceramic and glass phase capacitor both made in a photodefinable glass.

FIG. 12 shows a 30 GHz Ban Pass filter with Ceramic Phase Capacitors.

FIG. 13 shows 19 GHz Band Pass Filter of the present invention.

FIG. 14 shows a 28 GHz Band Pass Filter of the present invention.

FIG. 15 shows a 33 GHz Low Pass Filter of the present invention.

FIG. 16 shows a 20 GHz Band Pass Filter of the present invention.

FIG. 17 shows a 7 GHz Band Pass Filter of the present invention.

FIG. 18 shows a layout of a Doherty Amplifier design including the lumped elements that can be made using the present invention.

FIG. 19 shows a layout of a power divider/combiner that can be made using the present invention.

FIG. 20 shows a layout of a lumped element circulator when a termination resistor is connected to the circulator, it becomes an isolator and can be made using the present invention.

FIG. 21 shows glass-based system-in-a-package (SiP) with integrated lumped element devices of the present invention. The SiP is approximately 0.5 cm×0.5 cm.

FIG. 22 shows a sampling of glass-based SiP with integrated lumped element devices of the present invention.

### DETAILED DESCRIPTION OF THE INVENTION

While the making and using of various embodiments of the present invention are discussed in detail below, it should be appreciated that the present invention provides many applicable inventive concepts that can be embodied in a wide variety of specific contexts. The specific embodiments discussed herein are merely illustrative of specific ways to make and use the invention and do not delimit the scope of the invention.

To facilitate the understanding of this invention, a number of terms are defined below. Terms defined herein have meanings as commonly understood by a person of ordinary skill in the areas relevant to the present invention. Terms such as “a”, “an” and “the” are not intended to refer to only a singular entity but include the general class of which a specific example may be used for illustration. The terminology herein is used to describe specific embodiments of the invention, but their usage does not limit the invention, except as outlined in the claims.

The present invention eliminates the parasitic losses and signals associated with lumped element devices in the RF domain. Lumped element devices or an array of lumped element devices consist of capacitors, inductors, and resistors to implement a wide number of electronic devices and functions including: filters (band-pass, band-stop, high-pass, notch, low-pass filter), circulators, antenna, power conditioning, power combiner, power splitter, matching networks, isolators and/or Doherty power amplifier in photodefinable glass ceramic system-in-a-package (SiP) for microwave and radiofrequency that eliminates or greatly reduce parasitic signals or losses. The parasitic signals or losses are generated from the antenna effects combined with the inductance, capacitance and resistance from the packaging, solder bonding (ball grid), electronic connectors (wire), electrical bond pads and mounting elements that attach the packaged lumped element devices to the SiP. The distorted signals or losses are transmitted to other RF devices on the printed circuit board or substrate. There is sufficient variation in the traditional packaged and mounting of lumped elements to create large performance variations from the actual intended performance. These variations appear to be random due to the subtle differences in the packaging that force RF products to endure a large number of design iterations and/or manual trimming/correction to create a final RF circuit that meets the desired operating envelop. Eliminating the distortion associated with the RF packaging and the mounting elements allows the RF filter device to perform as designed/simulated. Integrating lumped element devices into a photodefinable glass ceramic SiP enables the circuit to perform as designed and simulated through the entire RF spectrum. These lumped element device structures consist of both the vertical as well as horizontal planes either separately or at the same time to form two or three-dimensional lumped element devices with design to device parity, lower loss, low signal distortion, reduced parasitic capacitance, reduced cost, and smaller physical size.

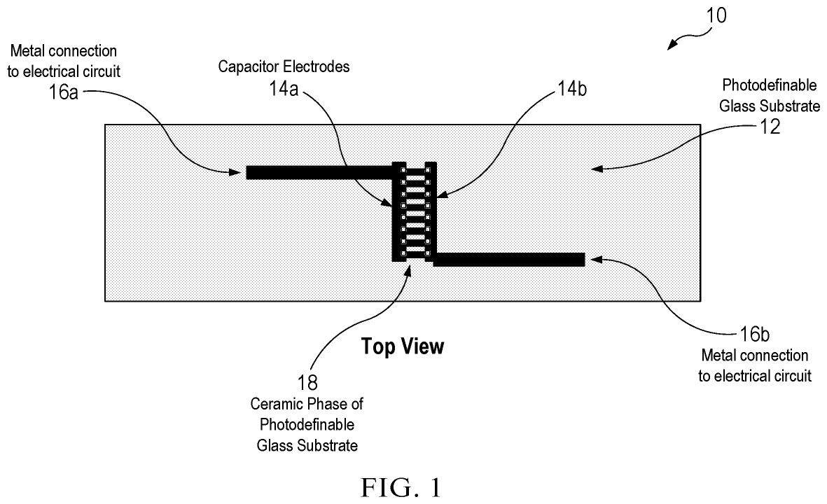

As described in the background, photosensitive glass structures have been suggested for a number of micromachining and microfabrication processes such as integrated electronic elements in conjunction with other elements systems or subsystems. The present invention has advantages over silicon microfabrication of traditional glass that is expensive and low yield while injection modeling or embossing processes produce inconsistent shapes and improved RF Q. The present invention has additional advantages over silicon microfabrication processes that rely on expensive capital equipment; photolithography and reactive ion etching or ion beam milling tools that generally cost in excess of one million dollars each and require an ultra-clean, high-production silicon fabrication facility costing millions to billions more. The present invention also overcomes the problems with injection molding and embossing that generate defects within the transfer or have differences due to the stochastic curing process. Ideal inductors would have zero resistance and zero capacitance. But, real inductors have “parasitic” resistance, inductors and capacitance. The first self-resonant frequency of an inductor is the lowest frequency at which an inductor resonates with its self-capacitance. The first resonance can be modeled by a combination of inductance and capacitance with a ceramic phase capacitor made in a photodefinable glass can further enhance the performance of an RF circuit/SiP through enhancing the Q of the circuit. This can be seen in FIG. 1. A resistor “RI” limits impedance near the resonant frequency at the self-resonant frequency (SRF) of an inductor, all of the following conditions are met: (1) The input impedance is at its peak; (2) the phase angle of the input impedance is zero, crossing from positive (inductive) to negative (capacitive); (3) since the phase angle is zero, the Q is zero; (4) the effective inductance is zero, since the negative capacitive reactance (Xc=1/jωC) just cancels the positive inductive reactance (XL=jωL); (5) the 2-port insertion loss (e.g. S21 dB) is a maximum, which corresponds to the minimum in the plot of frequency vs. S21 dB; and (6) the 2-port phase (e.g. S21) angle is zero, crossing from negative at lower frequencies to positive at higher frequencies.

To address these needs, the present inventors developed a glass ceramic (APEX® Glass ceramic) as a novel packaging and substrate material for semiconductors, RF electronics, microwave electronics, and optical imaging. APEX® Glass ceramic is processed using first generation semiconductor equipment in a simple three step process and the final material can be fashioned into either glass, ceramic, or contain regions of both glass and ceramic. The APEX® Glass ceramic enables the creation of an SiP that includes one or part of the following: easily fabricated high density vias, electronic devices including; Inductors, Ceramic phase Capacitors, Resistors, Transmission Lines, Coax Lines, Antenna, Microprocessor, Memory, Amplifier, Transistors, matching networks, RF Filters (Tank Circuits, Notch Filters, Band Pass Filters, Low Pass Filters, High Pass Filters and others), RF Circulators, RF Isolators, Impedance Matching Elements, 50 Ohm Termination Elements, Integrated Ground Planes, RF Shielding Elements, EMI Shielding Elements, RF Combiners, RF Splitters, Transformers, Switches, Multiplexors, and/or Diplexers.

Eliminating the losses, distortion/noise, parasitic signals and poor performance quality factor. The enhanced performance of lumped element devices with a ceramic phase capacitor that are integrated directly into the SiP have demonstrated dramatically improved functionality in RF/Microwave device that can now be coupled with small feature size. The directly integrated lumped element based devices into or on to the SiP include but are not limited to: RF Filters, RF Circulators, RF Isolators, Antenna, Impedance Matching Elements, 50 Ohm Termination Elements, Integrated Ground Planes, RF Shielding Elements, EMI Shielding Elements, RF Combiners, RF Splitters, Transformers, Switches, power splitters, power combiners, and/or Diplexors. These directly integrated lumped element devices on the SiP are connected with integrated circuits devices. These integrated circuits devices including but not limited to: microprocessors, multiplexers, switches, amplifiers, and memories.

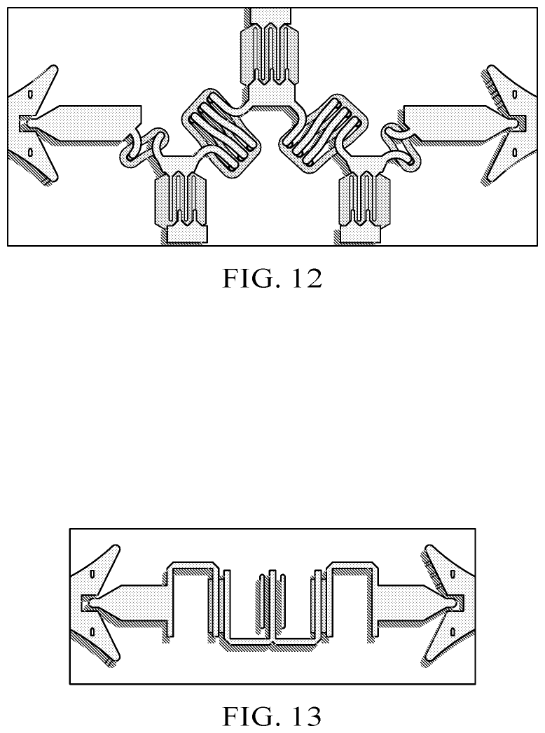

In particular a SiP with an integrated lump element RF device has been produced with design to device parity in APEX© Glass using conventional semiconductor processing equipment. The integrated lumped element RF filter in the APEX© Glass SiP can be seen in FIG. 12. The open area in the center of the SiP is for the placement of integrated circuits to complete the SiP. FIG. 13 shows a sampling of glass-based SiP with integrated lumped element devices of the present invention. Depending on size of the SiP there can be a great number of SiPs on a single wafer. The APEX© Glass wafer populated with over 500 SiP with the integrated lump element devices.

A SiP with a fully integrated lumped element device can be produced in a photo-definable glasses have high temperature stability, good mechanical a n d electrical properties, and have better chemical resistance than plastics and many metals. To the inventor's knowledge, the only commercial photo-definable glass is FOTURAN™, made by Schott Corporation. FOTURAN™ comprises a lithium-aluminum-silicate glass containing traces of silver ions. When exposed to UV-light within the absorption band of cerium oxide the cerium oxide acts as sensitizers, absorbing a photon and losing an electron that reduces neighboring silver oxide to form silver atoms, e.g.,

$$Ce 3 ++ Ag += Ce 4 ++ Ag 0$$

The silver atoms coalesce into silver nanoclusters during the baking process and induces nucleation sites for crystallization of the surrounding glass. If exposed to UV light through a mask, only the exposed regions of the glass will crystallize during subsequent heat treatment.

This heat treatment must be performed at a temperature near the glass transformation temperature (e.g., greater than 465° C. in air for FOTURAN™). The crystalline phase is more soluble in etchants, such as hydrofluoric acid (HF), than the unexposed vitreous, amorphous regions. In particular, the crystalline regions of FOTURAN™ are etched about 20 times faster than the amorphous regions in 10% HF, enabling microstructures with wall slopes ratios of about 20:1 when the exposed regions are removed. See T. R. Dietrich et al., “Fabrication technologies for microsystems utilizing photoetchable or photodefinable glass,” Microelectronic Engineering 30, 497 (1996), which is incorporated herein by reference.

Preferably, the shaped glass structure contains at least one or more, two or three-dimensional inductive devices. The inductive device is formed by making a series of connected loops to form a free-standing inductor. The loops can be either rectangular, circular elliptical, fractal or other shapes that create and pattern that generates induction. The patterned regions of the APEX© glass can be filled with metal, alloys, composites, glass or other magnetic media, by a number of methods including plating or vapor phase deposition. The magnetic permittivity of the media combined with the dimensions and number of structures (loops, turns or other inductive element) in the device provide the inductance of devices.

FOTURAN™ is described in information supplied by Invenios (the U.S. supplier for FOTURAN™) and is composed of silicon oxide (SiO₂) of 75-85% by weight, lithium oxide (Li₂O) of 7-11% by weight, aluminum oxide (Al₂O₃) of 3-6% by weight, sodium oxide (Na₂O) of 1-2% by weight, 0.2-0.5% by weight diantimony trioxide (Sb₂O₃) or arsenic oxide (As₂O₃), silver oxide (Ag₂O) of 0.05-0.15% by weight, and cerium oxide (CeO₂) of 0.01-0.04% by weight. As used herein the terms “APEX© Glass ceramic”, “APEX© glass” or simply “APEX©” is used to denote one embodiment of the glass ceramic composition of the present invention. The present invention provides a single material approach for the fabrication of ceramic phase capacitors used in a variety of filters and systems in a package.

Generally, glass ceramics materials have had limited success in microstructure formation plagued by performance, uniformity, usability by others and availability issues. Past glass-ceramic materials have an etch aspect-ratio of approximately 15:1 in contrast APEX© glass has an average etch aspect ratio greater than 50:1. This allows users to create smaller and deeper features. Additionally, our manufacturing process enables product yields of greater than 90% (legacy glass yields are closer to 50%). Lastly, in legacy glass ceramics, approximately only 30% of the glass is converted into the ceramic state, whereas with APEX® Glass ceramic this conversion is closer to 70%.

The APEX© Glass composition provides three main mechanisms for its enhanced performance: (1) The higher amount of silver leads to the formation of smaller ceramic crystals which are etched faster at the grain boundaries, (2) the decrease in silica content (the main constituent etched by the HF acid) decreases the undesired etching of unexposed material, and (3) the higher total weight percent of the alkali metals and boron oxide produces a much more homogeneous glass during manufacturing.

The present invention includes a method for fabricating a glass ceramic structure for use in forming inductive structures used in electromagnetic transmission, transformers and filtering applications. The present invention includes an inductive element device structures created in the multiple planes of a glass-ceramic substrate, such process employing the (a) exposure to excitation energy such that the exposure occurs at various angles by either altering the orientation of the substrate or of the energy source, (b) a bake step and (c) an etch step. Angle sizes can be either acute or obtuse. The curved and digital structures are difficult, if not infeasible to create in most glass, ceramic or silicon substrates. The present invention has created the capability to create such structures in both the vertical as well as horizontal plane for glass-ceramic substrates. The present invention includes a method for fabricating of an inductor structure on or in a glass ceramic.

Ceramicization of the glass is accomplished by exposing the entire glass substrate to approximately 20 J/cm² of 310 nm light. When trying to create glass spaces within the ceramic, users expose all of the material, except where the glass is to remain glass. In one embodiment, the present invention provides a quartz/chrome mask containing a variety of concentric circles with different diameters.

The present invention includes a method for fabricating an inductive device and ceramic phase capacitors in or on a photodefinable glass ceramic structure for DC electrical, microwave, radio frequency and millimeter wave applications. The glass ceramic substrate may be a photosensitive glass substrate having a wide number of compositional variations including but not limited to: 60-76 weight % silica; at least 3 weight % K₂O with 6 weight %-16 weight % of a combination of K₂O and Na₂O; 0.003-1 weight % of at least one oxide selected from the group consisting of Ag₂O and Au₂O; 0.003-2 weight % Cu₂O; 0.75 weight %-7 weight % B₂O₃, and 6-7 weight % Al₂O₃; with the combination of B₂O₃; and Al₂O₃ not exceeding 13 weight %; 8-15 weight % Li₂O; and 0.001-0.1 weight % CeO₂. This and other varied composition are generally referred to as the APEX® or photodefinable glass.

The exposed portion may be transformed into a crystalline material by heating the glass substrate to a temperature near the glass transformation temperature. When etching the glass substrate in an etchant such as hydrofluoric acid, the anisotropic-etch ratio of the exposed portion to the unexposed portion is at least 30:1 when the glass is exposed to a broad spectrum mid-ultraviolet (about 308-312 nm) flood lamp to provide a shaped glass structure that have an aspect ratio of at least 30:1, and to create an inductive structure. The mask for the exposure can be of a halftone mask that provides a continuous grey scale to the exposure to form a curved structure for the creation an inductive structure/device. A halftone mask or grey scale enables the control the device structure by controlling the exposure intensity undercut of a digital mask can also be used with the flood exposure to produce an inductive structure/device. The exposed glass is then typically baked in a two-step process. A temperature range of between of 420° C.-520° C. for between 10 minutes to 2 hours is used for the coalescing of silver ions into silver nanoparticles and a temperature range of between 520° C.-620° C. for between 10 minutes and 2 hours allows the lithium oxide to form around the silver nanoparticles. The glass plate is then etched. The glass substrate is etched in an etchant, of HF solution, typically 5% to 10% by volume, wherein the etch ratio of exposed portion to that of the unexposed portion is at least 30:1 when exposed with a broad spectrum mid-ultraviolet flood light, and greater than 30:1 when exposed with a laser, to provide a shaped glass structure with an anisotropic-etch.

A preferred ceramic phase capacitor structure where a rectangular bind via or other structure. The rectangular bind via structure is created by exposing the region with sufficient energy 20 J/cm² for 80% of the time require to create a through hole via and then baked at 620° C. for at least 10 min. The converted ceramic region is then etched using a 10% HF solution leaving a thinned region of the photodefinable glass. Using the same mask that defined the rectangular blind via with 20 J/cm² with 100% the time. This creates a thinned ceramic region of the photo-definable glass. Using the same rectangular mask to create a photoresist pattern that exposes the thin ceramic region of the photodefinable glass. The exposed rectangular pattern is metallized with a flash coating (<0.5 μm) of nickel from a sputtering system. The wafer is then placed in a photoresist stripper to remove the photoresist. The wafer is then rinsed with DI water and dried. The wafer is then placed in an electroplating bath of electroless copper.

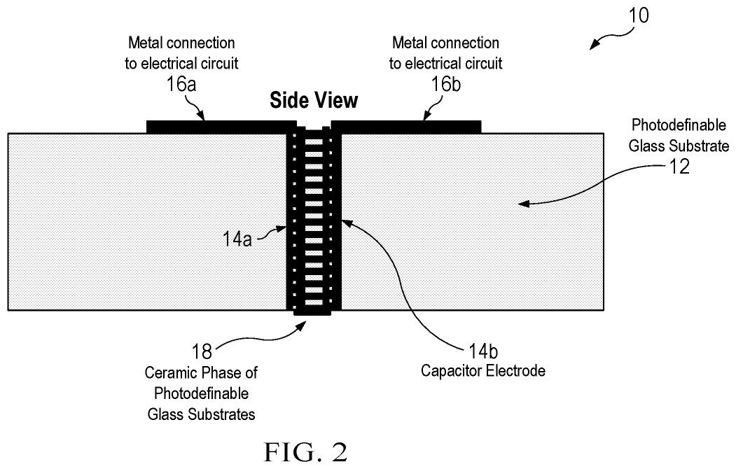

The ceramic capacitor may also be made where the ceramic dialectic layer is normal (perpendicular) to the substrate. The two rectangular patterns are exposed with 20 J/cm² with 100% the time required to create a through hole via. One structure of the present invention can be seen in FIG. 1 and FIG. 2. FIG. 1 is a top view of one embodiment of the capacitor 10 of the present invention, in which the capacitor 10 is shown on a photodefinable glass substrate 12 on which capacitor electrodes 14a, 14b are shown, in this case shown as interdigitated. Metal connections 16a, 16b are shown that connected each of the capacitor electrodes 14a, 14b, to separate electrical circuits (not depicted). A ceramic phase 18 of the photodefinable glass substrate us depicted between the capacitor electrodes 14a, 14b.

FIG. 2 shows a side view of the capacitor 10 of the present invention, in which the capacitor 10 includes capacitor electrodes 14a, 14b are shown on the photodefinable glass substrate 12 are shown, in this case shown as interdigitated. Metal connections 16a, 16b are shown that connected each of the capacitor electrodes 14a, 14b, to separate electrical circuits (not depicted). A ceramic phase 18 of the photodefinable glass substrate as depicted between the capacitor electrodes 14a, 14b.

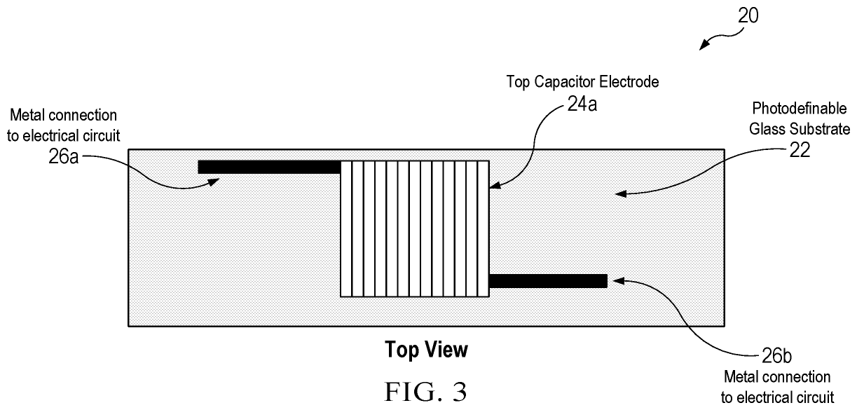

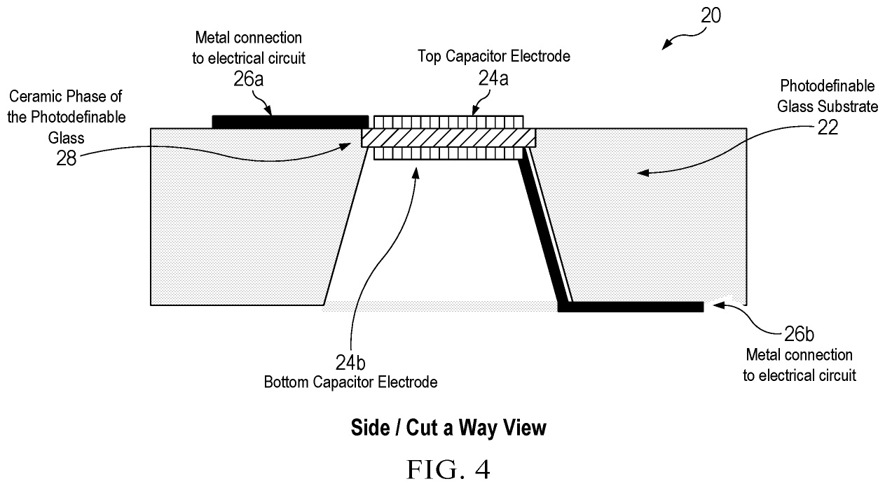

FIG. 3 shows a top view of another embodiment of the capacitor 10 of the present invention, in which the capacitor 20 is shown on a photodefinable glass substrate 22 on which top capacitor electrode 24a is shown. Metal connections 26a, 26b are shown that connected each of the top capacitor electrode 24a and 24b (see FIG. 4), which connect to separate electrical circuits.

FIG. 4 is a side/cut away view of the capacitor 20 of the present invention, in which the capacitor 20 in which top capacitor electrode 24a and bottom capacitor electrode 24b are shown on the photodefinable glass substrate 22. Metal connections 26a, 26b are shown that connected each of the capacitor electrodes 24a, 24b, to separate electrical circuits (not depicted). A ceramic phase 28 of the photodefinable glass substrate as depicted between the capacitor electrodes 24a, 24b.

The capacitor 20 shown in FIG. 3 and FIG. 4 can be accomplished by exposing two rectangular patterns. The two patterns are 20 μm wide and 20 μm long and separated by at least 15 μm. The photoresist is then removed using a standard photoresist stripper. The wafer is then placed into an of and baked at 620° C. for at least 10 min. The rectangular pattern has been converted to a ceramic phase of the photodefinable glass. The two parallel rectangular patterns are then etched with 10% HF. The remaining glass phase of the photodefinable glass that separates the two rectangular through hole vias is exposed with 20 J/cm² with 100% of the time required to create a through hole via. The photodefinable wafer is then baked at 620° C. for at least 10 min to convert the spacer region to the ceramic phase of the photodefinable glass. The through hole vias are then filled using standard electroplating process.

Both or these capacitor structures are connected to the rest of the circuit or to bonding pads to via standard copper metallization using a seed layer of Titanium that is 200 Å thick using a sputtering metallization system or other thin film deposition system. Next copper metal is deposited by electroless deposition. The copper and seed layer are patterned and etch using a standard photoresist and coper etching processes.

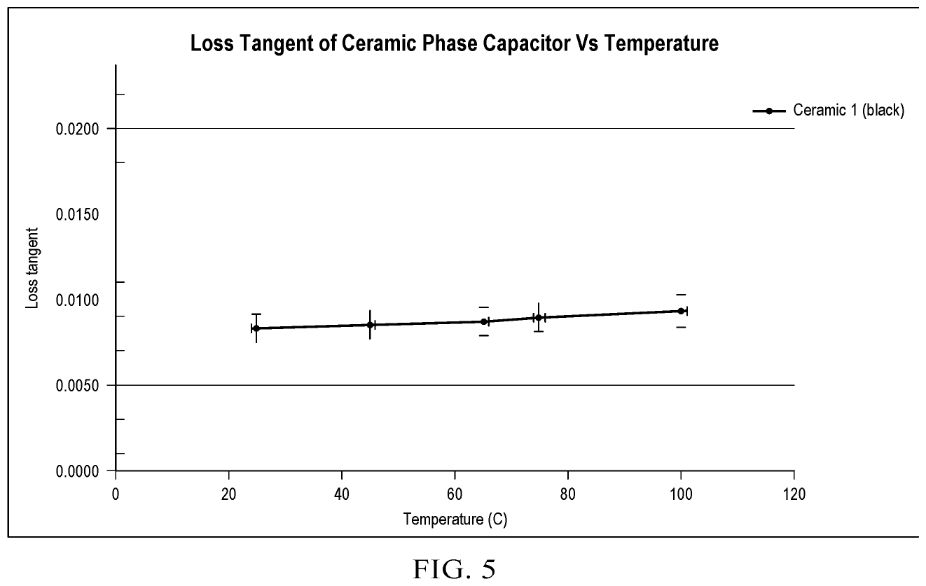

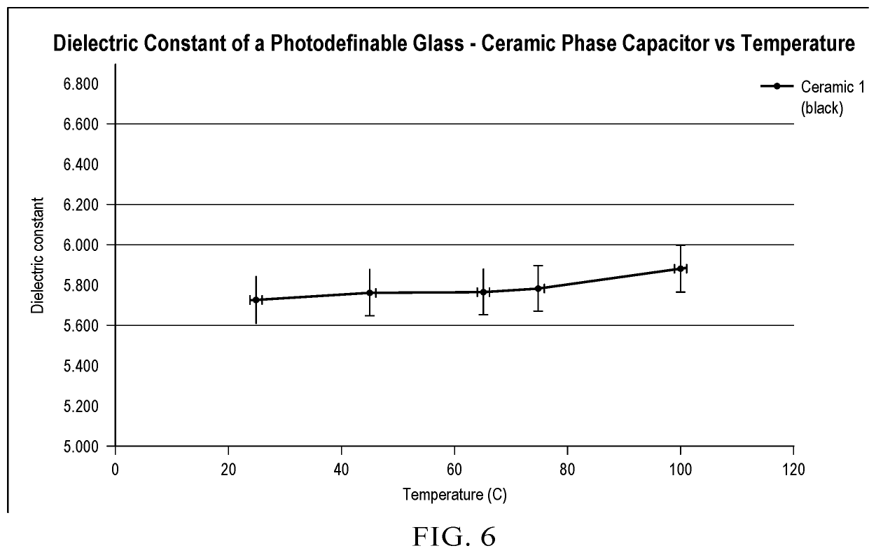

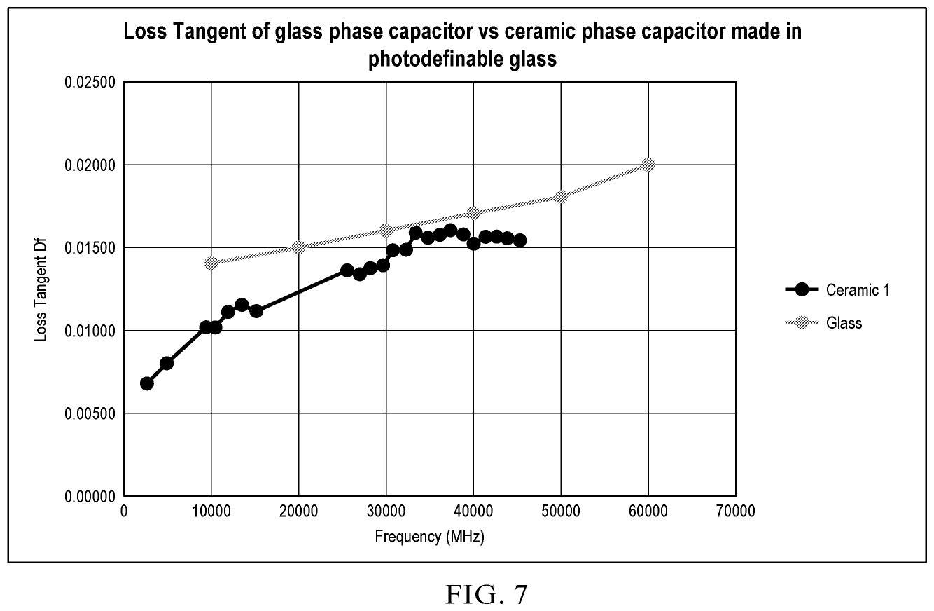

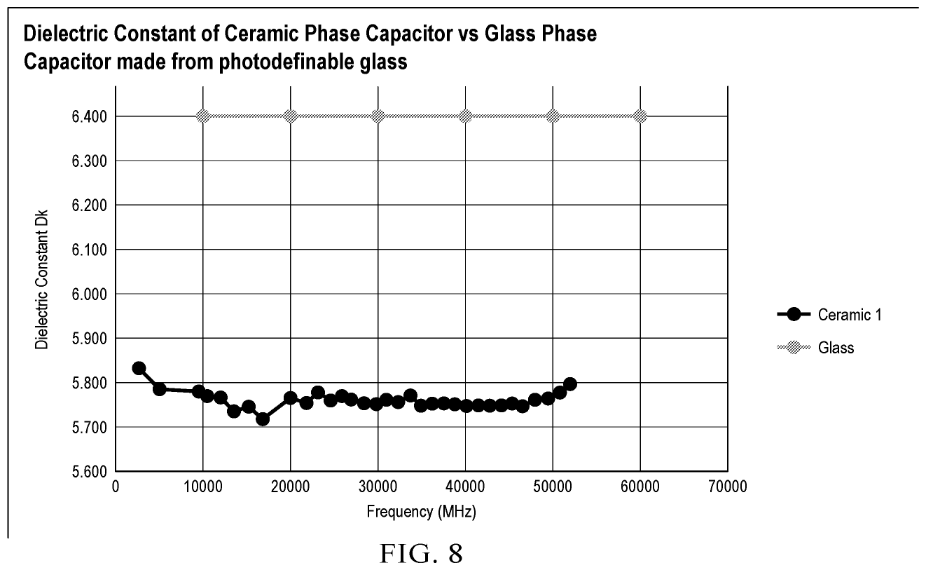

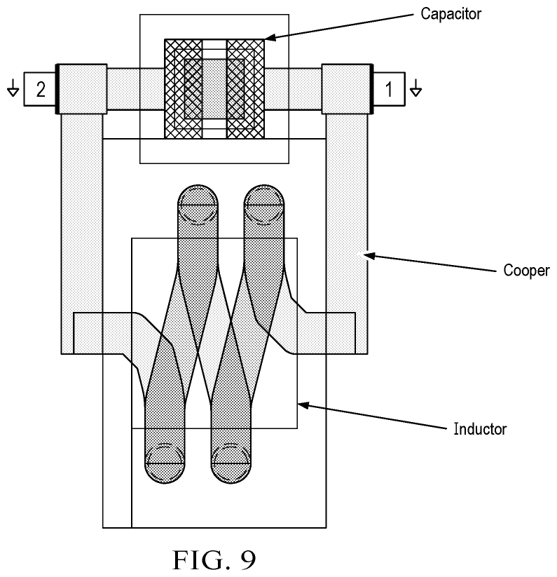

Both of these and other capacitor structures made in the ceramic phase of the photodefinable glass have significantly better performance relative to a glass phase capacitor. There is a slight reduction in dielectric constant in the ceramic phase relative to the glass phase capacitor see in FIG. 8. This can be compensated for by making small changes in the area or thickness of the ceramic phase capacitor structure. That said, the lower lost tangent and temperature stability in the ceramic phase capacitor has a significant performance advantage in RF electronics. The temperature stability can be seen in FIG. 5 and FIG. 6. The lower loss tangent enables better performance in battery life-time, signal to noise, transmission power and other critical system attributes. These enhance performance attributes are a combination of material properties, such as the loss tangent, but also due to the precision of the production process. The precision production process produces RF capacitors and inductors with tolerance better than +/−5%.

### Integrated Inductor.

The glass substrate is then etched in an etchant, of HF solution, typically 5% to 10% by volume. The fully integrated inductor lumped element device(s) structure is created creating by:

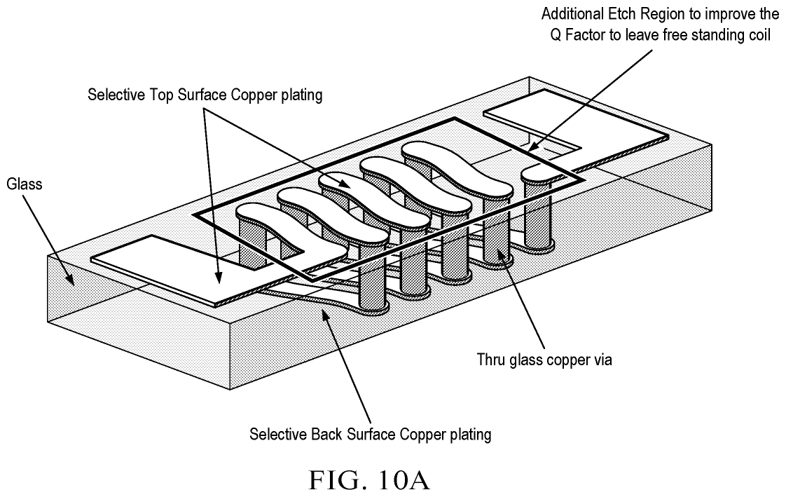

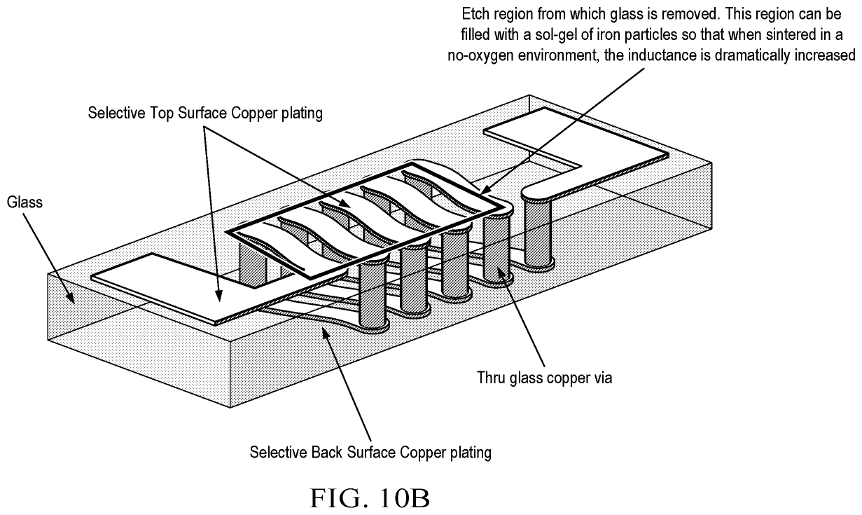

The process of making an inductive device using the present invention shows the starting material that is a photodefinable glass, which can be a wafer and may preferably be an APEX® Glass of, e.g., a 1 mm thickness with a surface roughness less than or equal to 50 nm and surface to surface parallel less than or equal to 10% with an RMS roughness <200 Å. In this example, a resistor section of SiP and its manufacture is shown. Expose a pattern of through hole vias spaced 75 μm apart center to center with a 20 μm diameter. Please see FIG. 10 for the specific placement of the trough hole vias. Next, electroplate copper to fill the vias. The excess copper can be removed using a CMP process to planarize the surface.

The copper filled through glass structure and the APEX© glass substrate is exposed using a second photo mask that has a pattern to connect the via for the inductors. The ceramic vias are etched preferential to the glass using a 10% HF solution. The wafer is then cleaned with DI water and spun dry. The vias are filled by preferential electroless plating of copper in the vias. The substrate and excess copper plating is then removed using a traditional CMP process. See FIG. 10.

Next, expose the photodefinable glass wafer from using, a photomask to create a trench/rectangle a pattern in the photodefinable glass. The photodefinable glass is exposed to a radiation at 310 nm with an intensity ˜20 J/cm² and baked at 600° C. in argon for 10 min as to convert the exposed pattern to a ceramic phase.

The photodefinable glass wafer with a metal connection between the copper filled through hole vias. A pattern is exposed and developed following the standard process to create a pattern through the photoresists that a resistor layer can be deposited. The wafer is exposed to a light O₂ plasma to remove any residual organic material in the pattern. Next, a thin film (300 Å) of nickel is deposited using a DC sputter metallization process. The photoresist is then removed using a standard photoresists stripper. The pattern thin film of nickel is placed into an electroless copper plating bath where 10 μm of copper are plated on the patterned nickel. The process of completing the inductor is achieved by placing the substrate into a 10% HF solution to remove the rectangular patterned ceramic phase. The inductor can be connected to the capacitor of the present invention.

Remove the glass/ceramic material identified as the material within the rectangular outline of the inductor to enable the coils to be free standing to improve the Quality Factor or Q of the inductor.

### Integrated Resistor.

The photodefinable glass wafer with a resistor is created by first creating the desired dimension resistor using a standard lift-off process. A pattern is exposed and developed following the standard process to create a pattern through the photoresists that a resistor layer can be deposited. The wafer is exposed to a light O₂ plasma to remove any residual organic material in the pattern. Typically, this is accomplished at 0.1 mTorr with 200 W forward power for 1 min. Next, a metallization layer 18 is deposited, e.g., a thin film of tantalum, titanium TiN, TiW, NiCr or other similar media. Typically, the deposition is accomplished by a vacuum deposition. The vacuum deposition of a seed layer can be accomplished by DC sputtering of tantalum through a liftoff pattern on to the glass substrate at a rate of 40 Å/min. The integrated resistor can be connected to the capacitor of the present invention.

### Integrated Ceramic Phase IPD Performance.

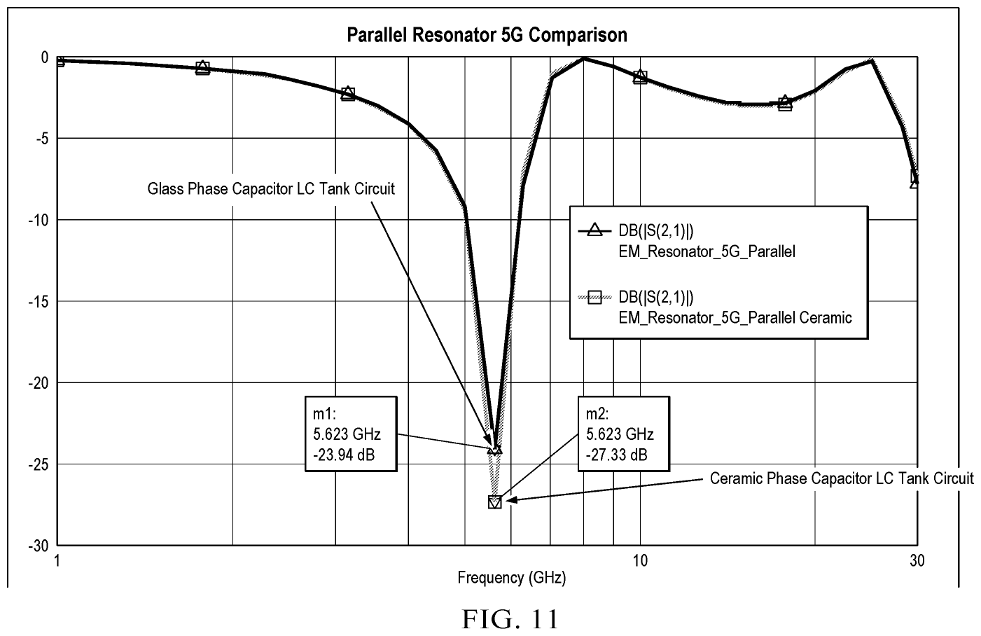

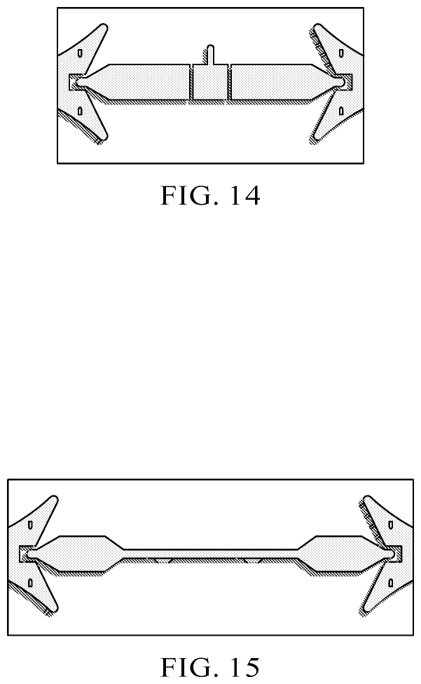

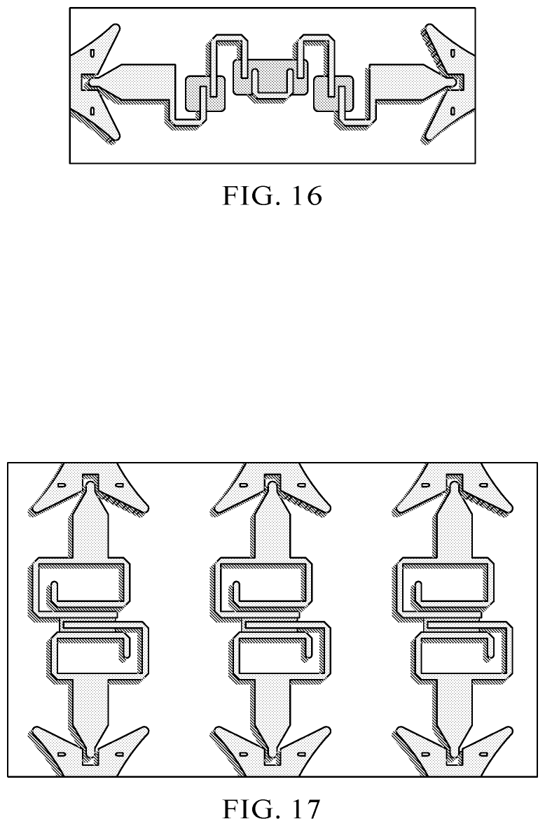

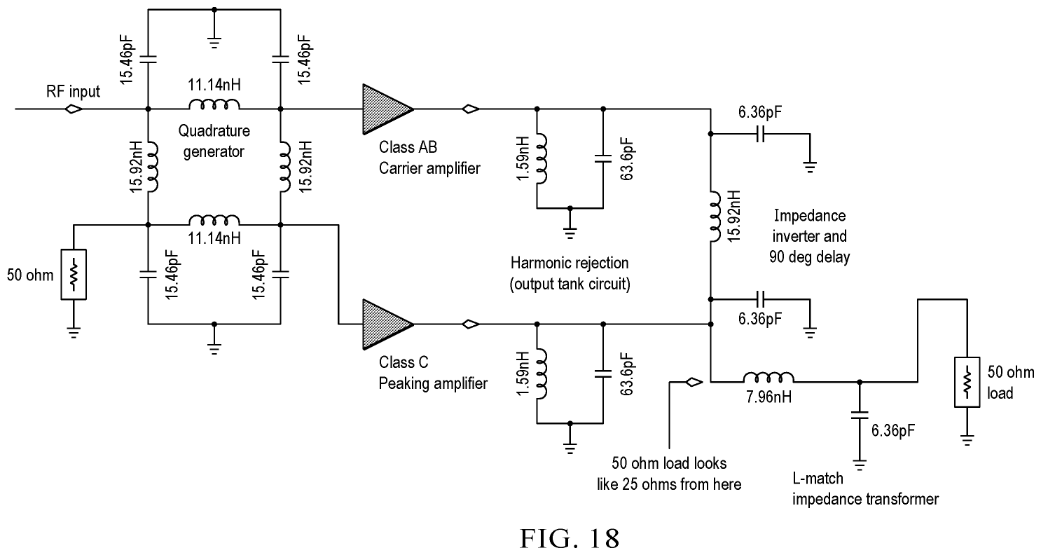

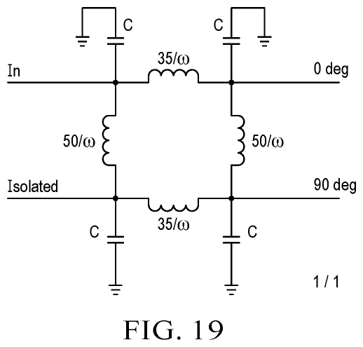

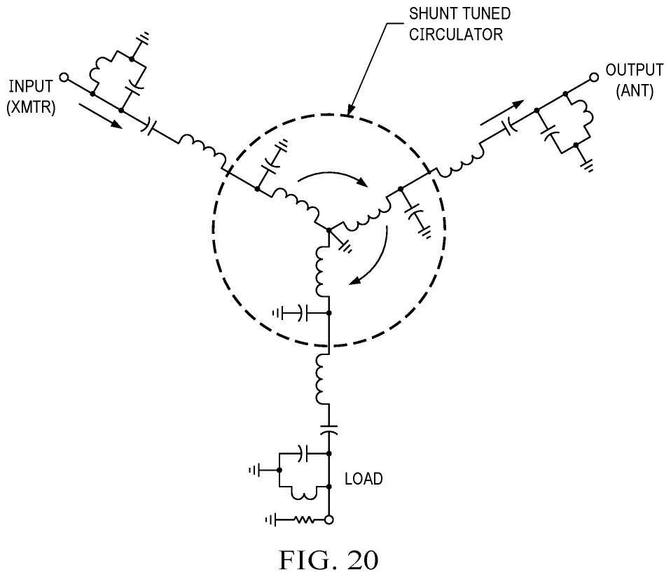

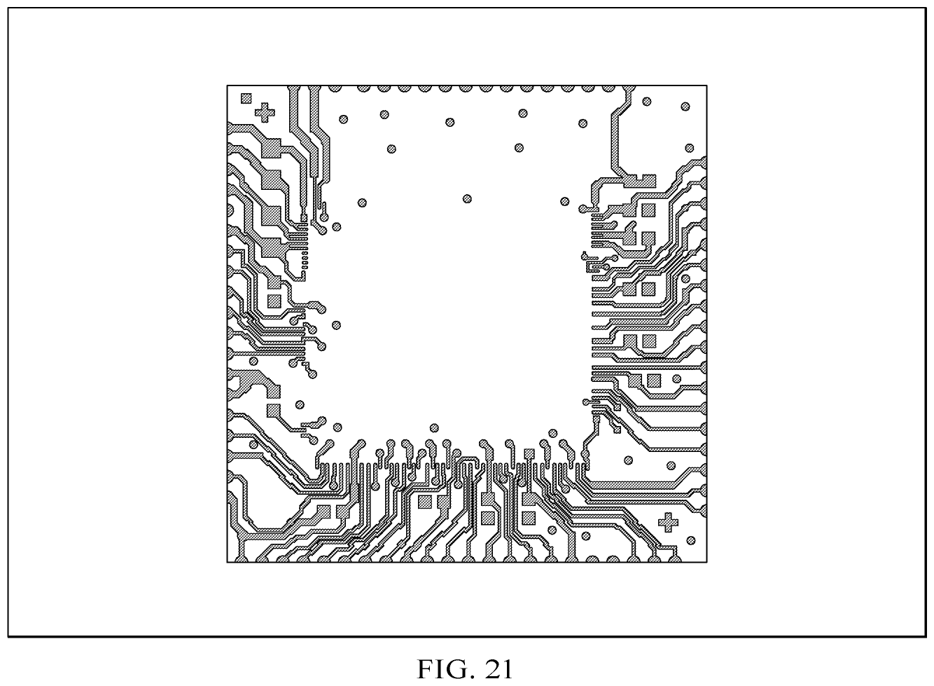

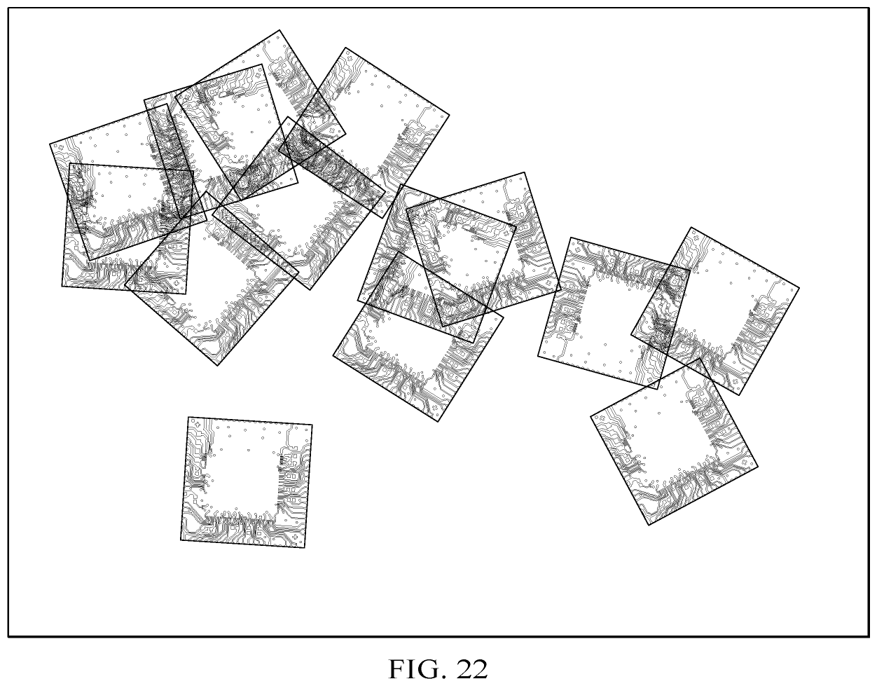

This manufacturing precision, better material properties and temperature stability enables higher performing and lower loss RF circuitry. Images of different types of filters can be seen in figures FIG. 12 through FIG. 17. The images show Band Pass and low pass filter made with Ceramic Phase Capacitors. FIG. 18 through FIG. 20 shows a layout/designs of Doherty Amplifier, power divider/combiner and circulator using the lumped elements that can be made using the present invention. The combined performance of the ceramic phase capacitor filter relative to a filter with a glass phase capacitor can be seen in the filter in FIG. 11. Although it may seem small due to the scale the enhancement provides a 3 dB (27 dB to 24 dB) or 50% improvement in the Q of the RF circuit/filter.

Although the present invention and its advantages have been described in detail, it should be understood that various changes, substitutions and alterations can be made herein without departing from the spirit and scope of the invention as defined by the appended claims. In some cases where the desired circuit performance or material compatibility the SiP may choose to use a SMD version of a resistor, capacitor, or inductor, in lieu of one of the photo-definable glass-based devices. Using an SMD version of one or more of the elements will contribute to the parasitic generated noise of the SiP requiring extra care in the assembly and packaging. Moreover, the scope of the present patent application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

In one embodiment, the present invention includes a method for creating a ceramic phase capacitor in or on photo-definable glass comprising, consisting essentially of, or consisting of the steps of: forming two or more capacitor electrodes of the ceramic phase capacitor on or in a photosensitive glass substrate, wherein a portion of the photosensitive glass substrate separates the two or more capacitor electrodes; exposing the portion of the photosensitive glass substrate that separates the two or more capacitor electrodes to an activating energy source; heating the photosensitive glass substrate above a glass transition temperature thereof for at least ten minutes; cooling the photosensitive glass substrate to transform the exposed portion of the photosensitive glass substrate to a glass-crystalline dielectric; and forming electrical connections to the two or more capacitor electrodes. In one aspect, the method further comprises forming the two or more capacitor electrodes in vias within the photosensitive glass substrate. In another aspect, the method further comprises forming the two or more capacitor electrodes on opposite surfaces of the photosensitive glass substrate. In another aspect, the method further comprises forming the glass-crystalline dielectric on a surface parallel to the photosensitive glass substrate, wherein the glass-crystalline dielectric is in a ceramic phase. In another aspect, the method further comprises connecting the ceramic phase capacitor to an isolator with integrated lump element devices in a system-in-a-package (SiP). In another aspect, the method further comprises connecting the ceramic phase capacitor to a circulator with integrated lump element devices in a SiP. In another aspect, the method further comprises connecting the ceramic phase capacitor to an RF filter with integrated lump element devices in a SiP. In another aspect, the method further comprises connecting the ceramic phase capacitor to at least one of a low-pass filter, a high-pass filter, a notch filter, a band-pass filter, or a transformer with integrated lump element devices in a SiP. In another aspect, the method further comprises connecting the ceramic phase capacitor to a power combiner or a power splitter in or on the photosensitive glass substrate. In another aspect, the method further comprises connecting the ceramic phase capacitor to one or more antennas, impedance matching elements, 50-ohm termination elements, integrated ground planes, RF shielding elements, electromagnetic interference shielding elements, RF Combiners, RF Splitters, transformers, switches, or diplexers.

In another embodiment, the present invention includes a ceramic phase capacitor device formed in or on a photosensitive glass substrate comprising, consisting essentially of, or consisting of: a first capacitor electrode formed in or on the photosensitive glass substrate; a glass-crystalline dielectric formed in situ from the photosensitive glass substrate adjacent to the first capacitor electrode; and a second capacitor electrode formed in or on the photosensitive glass substrate adjacent to the glass-crystalline dielectric and opposite the first electrode. In one aspect, the first and second capacitor electrodes are formed in vias within the photosensitive glass substrate. In another aspect, the first and second capacitor electrodes are formed on opposite surfaces of the photosensitive glass substrate. In another aspect, the glass-crystalline dielectric is formed on a surface parallel to the photosensitive glass substrate. In another aspect, the device further comprises a first metal connector connected to the first capacitor electrode and a second metal connector connected to the second capacitor electrode. In another aspect, the ceramic phase capacitor is connected to an isolator with integrated lump element devices and is in a SiP. In another aspect, the ceramic phase capacitor is connected to a circulator with integrated lump element devices and is in a SiP. In another aspect, the ceramic phase capacitor is connected to an RF filter with integrated lump element devices and is in a SiP. In another aspect, the ceramic phase capacitor is connected to at least one of a low-pass filter, a high-pass filter, a notch filter, a band-pass filter, transformer with integrated lump element devices and is in a SiP. In another aspect, the ceramic phase capacitor is connected to a power combiner or a power splitter in or on the photosensitive glass substrate. In another aspect, the ceramic phase capacitor is connected to one or more antennas, impedance matching elements, 50-ohm termination elements, integrated ground planes, RF shielding elements, electromagnetic interference shielding elements, RF combiners, RF splitters, transformers, switches, power splitters, power combiners, or diplexers.

In another embodiment, the present invention includes a method for creating a ceramic phase capacitor in or on photo-definable glass comprising, consisting essentially of, or consisting of the steps of: forming two or more capacitor electrodes of the ceramic phase capacitor on or in a photosensitive glass substrate, wherein a portion of the photosensitive glass substrate separates the two or more capacitor electrodes; exposing the portion of the photosensitive glass substrate that separates the two or more capacitor electrodes to an activating energy source; heating the photosensitive glass substrate above a glass transition temperature thereof for at least ten minutes; cooling the photosensitive glass substrate to transform the exposed portion of the photosensitive glass substrate to a glass-crystalline dielectric; and forming electrical connections to the two or more capacitor electrodes. In one aspect, the method further comprises forming the two or more capacitor electrodes in vias within the photosensitive glass substrate. In another aspect, the method further comprises forming the two or more capacitor electrodes on opposite surfaces of the photosensitive glass substrate. In another aspect, the method further comprises forming the glass-crystalline dielectric on a surface parallel to the photosensitive glass substrate, wherein the glass-crystalline dielectric is in a ceramic phase. In another aspect, the method further comprises connecting the ceramic phase capacitor to an isolator with integrated lump element devices in a SiP. In another aspect, the method further comprises connecting the ceramic phase capacitor to a circulator with integrated lump element devices in a SiP. In another aspect, the method further comprises connecting the ceramic phase capacitor to an RF filter with integrated lump element devices in a SiP. In another aspect, the method further comprises connecting the capacitor to at least one of a low-pass filter, a high-pass filter, a notch filter, a band-pass filter, or a transformer with integrated lump element devices in a SiP. In another aspect, the method further comprises connecting the capacitor to a power combiner or a power splitter in or on the photosensitive glass substrate. In another aspect, the method further comprises connecting the capacitor to one or more antennas, impedance matching elements, 50-ohm termination elements, integrated ground planes, RF shielding elements, electromagnetic interference shielding elements, RF Combiners, RF splitters, transformers, switches, power splitters, power combiners, or diplexers.

It is contemplated that any embodiment discussed in this specification can be implemented with respect to any method, kit, reagent, or composition of the invention, and vice versa. Furthermore, compositions of the invention can be used to achieve methods of the invention.

It will be understood that particular embodiments described herein are shown by way of illustration and not as limitations of the invention. The principal features of this invention can be employed in various embodiments without departing from the scope of the invention. Those skilled in the art will recognize, or be able to ascertain using no more than routine experimentation, numerous equivalents to the specific procedures described herein. Such equivalents are considered to be within the scope of this invention and are covered by the claims.

All publications and patent applications mentioned in the specification are indicative of the level of skill of those skilled in the art to which this invention pertains. All publications and patent applications are herein incorporated by reference to the same extent as if each individual publication or patent application was specifically and individually indicated to be incorporated by reference.

The use of the word “a” or “an” when used in conjunction with the term “comprising” in the claims and/or the specification may mean “one,” but it is also consistent with the meaning of “one or more,” “at least one,” and “one or more than one.” The use of the term “or” in the claims is used to mean “and/or” unless explicitly indicated to refer to alternatives only or the alternatives are mutually exclusive, although the disclosure supports a definition that refers to only alternatives and “and/or.” Throughout this application, the term “about” is used to indicate that a value includes the inherent variation of error for the device, the method being employed to determine the value, or the variation that exists among the study subjects.

As used in this specification and claim(s), the words “comprising” (and any form of comprising, such as “comprise” and “comprises”), “having” (and any form of having, such as “have” and “has”), “including” (and any form of including, such as “includes” and “include”) or “containing” (and any form of containing, such as “contains” and “contain”) are inclusive or open-ended and do not exclude additional, unrecited elements or method steps. In embodiments of any of the compositions and methods provided herein, “comprising” may be replaced with “consisting essentially of” or “consisting of”. As used herein, the phrase “consisting essentially of” requires the specified integer(s) or steps as well as those that do not materially affect the character or function of the claimed invention. As used herein, the term “consisting” is used to indicate the presence of the recited integer (e.g., a feature, an element, a characteristic, a property, a method/process step or a limitation) or group of integers (e.g., feature(s), element(s), characteristic(s), property(ies), method/process steps or limitation(s)) only.

The term “or combinations thereof” as used herein refers to all permutations and combinations of the listed items preceding the term. For example, “A, B, C, or combinations thereof” is intended to include at least one of: A, B, C, AB, AC, BC, or ABC, and if order is important in a particular context, also BA, CA, CB, CBA, BCA, ACB, BAC, or CAB. Continuing with this example, expressly included are combinations that contain repeats of one or more item or term, such as BB, AAA, AB, BBC, AAABCCCC, CBBAAA, CABABB, and so forth. The skilled artisan will understand that typically there is no limit on the number of items or terms in any combination, unless otherwise apparent from the context.

As used herein, words of approximation such as, without limitation, “about”, “substantial” or “substantially” refers to a condition that when so modified is understood to not necessarily be absolute or perfect but would be considered close enough to those of ordinary skill in the art to warrant designating the condition as being present. The extent to which the description may vary will depend on how great a change can be instituted and still have one of ordinary skilled in the art recognize the modified feature as still having the required characteristics and capabilities of the unmodified feature. In general, but subject to the preceding discussion, a numerical value herein that is modified by a word of approximation such as “about” may vary from the stated value by at least ±1, 2, 3, 4, 5, 6, 7, 10, 12 or 15%.

All of the compositions and/or methods disclosed and claimed herein can be made and executed without undue experimentation in light of the present disclosure. While the compositions and methods of this invention have been described in terms of preferred embodiments, it will be apparent to those of skill in the art that variations may be applied to the compositions and/or methods and in the steps or in the sequence of steps of the method described herein without departing from the concept, spirit and scope of the invention. All such similar substitutes and modifications apparent to those skilled in the art are deemed to be within the spirit, scope and concept of the invention as defined by the appended claims.

1. A method for creating a ceramic phase capacitor in or on photo-definable glass comprising:
forming two or more capacitor electrodes of the ceramic phase capacitor on opposite surfaces of a photosensitive glass substrate or in vias within the photosensitive glass substrate, wherein a portion of the photosensitive glass substrate separates the two or more capacitor electrodes;
exposing the portion of the photosensitive glass substrate that separates the two or more capacitor electrodes to an activating energy source;
heating the photosensitive glass substrate above a glass transition temperature thereof for at least ten minutes;
cooling the photosensitive glass substrate to transform the exposed portion of the photosensitive glass substrate to a glass-crystalline dielectric; and
forming electrical connections to the two or more capacitor electrodes.

2. (canceled)

3. (canceled)

4. The method of claim 1, further comprising forming the glass-crystalline dielectric on a surface parallel to the photosensitive glass substrate, wherein the glass-crystalline dielectric is in a ceramic phase.

5. The method of claim 1, further comprising connecting the ceramic phase capacitor to an isolator with integrated lump element devices in a system-in-a-package (SiP).

6. The method of claim 1, further comprising connecting the ceramic phase capacitor to a circulator with integrated lump element devices in a SiP.

7. The method of claim 1, further comprising connecting the ceramic phase capacitor to an RF filter with integrated lump element devices in a SiP.

8. The method of claim 1, further comprising connecting the ceramic phase capacitor to at least one of a low-pass filter, a high-pass filter, a notch filter, a band pass filter, or a transformer, with integrated lump element devices in a SiP.

9. The method of claim 1, further comprising connecting the ceramic phase capacitor to a power combiner or a power splitter in or on the photosensitive glass substrate.

10. The method of claim 1, further comprising connecting the ceramic phase capacitor to one or more antennas, impedance matching elements, 50-ohm termination elements, integrated ground planes, RF shielding elements, electromagnetic interference shielding elements, RF Combiners, RF Splitters, transformers, switches, or diplexers.

11. A ceramic phase capacitor device formed in or on a photosensitive glass substrate comprising:
a first capacitor electrode formed in vias within the photosensitive glass substrate or on a first surface of the photosensitive glass substrate;
a glass-crystalline dielectric formed in situ from the photosensitive glass substrate adjacent to the first capacitor electrode; and
a second capacitor electrode formed in vias within the photosensitive substrate or on the photosensitive glass substrate adjacent to the glass-crystalline dielectric and on a second surface opposite the first electrode.

12. (canceled)

13. (canceled)

14. The device of claim 11, wherein the glass-crystalline dielectric is formed on a surface parallel to the photosensitive glass substrate.

15. The device of claim 11, further comprising a first metal connector connected to the first capacitor electrode and a second metal connector connected to the second capacitor electrode.

16. The device of claim 11, wherein the ceramic phase capacitor is connected to an isolator with integrated lump element devices and is in a system-in-a-package (SiP).

17. The device of claim 11, wherein the ceramic phase capacitor is connected to a circulator with integrated lump element devices and is in a SiP.

18. The device of claim 11, wherein the ceramic phase capacitor is connected to an RF filter with integrated lump element devices and is in a SiP.

19. The device of claim 11, wherein the ceramic phase capacitor is connected to at least one of a low-pass filter, a high-pass filter, a notch filter, a band-pass filter, or a transformer with integrated lump element devices and is in a SiP.

20. The device of claim 11, wherein the ceramic phase capacitor is connected to a power combiner or a power splitter in or on the photosensitive glass substrate.

21. The device of claim 11, wherein the ceramic phase capacitor is connected to one or more antennas, impedance matching elements, 50-ohm termination elements, integrated ground planes, RF shielding elements, electromagnetic interference shielding elements, RF combiners, RF splitters, transformers, switches, power splitters, power combiners, or diplexers.

22.-28. (canceled)
